(19) United States
(12) Patent Application Publication
(10) Pub. No.: US 2015/0369539 A1
(43) Pub. Date: Dec. 24, 2015

(54) APPARATUS FOR PROCESSING SUBSTRATE

(71) Applicant: EUGENE TECHNOLOGY CO., LTD., Cheoin-gu, Yongin-si Gyeonggi-do (KR)

(72) Inventors: Il-Kwang YANG, Gyeonggi-do (KR); Byoung-Gyu SONG, Gyeonggi-do (KR); kyong-Hun KIM, Gyeonggi-do (KR); Yong-Ki KIM, Chungcheongnam-do (KR); Yang-Sik SHIN, Gyeonggi-do (KR)

(73) Assignee: EUGENE TECHNOLOGY CO., LTD., Gyeonggi-do (KR)

(21) Appl. No.: 14/766,289

(22) PCT Filed: Feb. 17, 2014
(86) PCT No.: PCT/KR2014/001256

§ 371 Date: Aug. 6, 2015

(30) Foreign Application Priority Data
Mar. 27, 2013 (KR) 10-2013-0032995

(51) Int. Cl. F27B 1/24; H01L 21/67; F27B 1/08

(52) U.S. Cl. CPC F27B 1/24; F27B 1/08; H01L 21/67109

(57) ABSTRACT

Provided is a substrate processing apparatus. The substrate processing apparatus includes a process chamber having an inner space in which a substrate transferred from the outside is accommodated, and a process with respect to the substrate is performed and a tube type heater disposed around the inner space in a sidewall of the process chamber, the tube type heater having a passage through which a refrigerant supplied from the outside flows.

### TECHNICAL FIELD

The present invention disclosed herein relates to an apparatus for processing a substrate, and more particularly, to a substrate processing apparatus in which a heater installed within a process chamber for performing processes with respect to a substrate and an internal temperature of the process chamber are easily cooled.

### BACKGROUND ART

Substrate processing apparatuses used for manufacturing semiconductors, flat panel displays, photovoltaic cells, and the like may be apparatuses that perform an essential thermal processing process for crystallizing and phase-changing a predetermined thin film that is deposited on a substrate such as a silicon wafer or a glass substrate.

Typically, in case of manufacturing liquid crystal displays or thin-film crystalline silicon photovoltaic cells, there is a silicon crystallization apparatus for crystallizing amorphous silicon deposited on the a glass substrate into poly silicon. To perform the crystallization process, the substrate on which the predetermined thin film is formed has to be heated. For example, it is necessary that a process temperature for crystallizing the amorphous silicon is about 550° C. to about 600° C.

Such a substrate processing apparatus may be classified into a single wafer type substrate processing apparatus in which a substrate processing process is performed on one substrate and a batch type substrate processing apparatus in which a substrate processing process is performed on a plurality of substrates. The single wafer type substrate processing apparatus has an advantage in that its structure is simple. However, the single wafer type substrate process apparatus may be deteriorated in productivity. Thus, the batch type substrate processing apparatus may be in the spotlight.

### DISCLOSURE

### Technical Problem

The present invention provides a substrate processing apparatus in which a heater for heating a substrate and an internal temperature of a process chamber are easily cooled.

Further another object of the present invention will become evident with reference to following detailed descriptions and accompanying drawings.

### Technical Solution

Embodiments of the present invention provide substrate processing apparatuses including: a process chamber having an inner space in which a substrate transferred from the outside is accommodated, and a process with respect to the substrate is performed; and a tube type heater disposed around the inner space in a sidewall of the process chamber, the tube type heater having a passage through which a refrigerant supplied from the outside flows.

In some embodiments, the process chamber may include: an inlet port disposed on one side of the process chamber to allow the tube type heater to be taken in; and an outlet port disposed on the other side of the process chamber to allow the tube type heater to be taken out, wherein the substrate processing apparatus may further include: a supply line connected to the tube type heater disposed on the inlet port to supply the refrigerant; and a discharge line connected to the tube type heater disposed on the outlet port to discharge the refrigerant within the tube type heater.

In other embodiments, the substrate processing apparatuses may further include: an insulation connection part connecting the tube type heater to each of the supply and discharge lines; a power source disposed between the process chamber and the insulation connection part to supply current to the tube type heater; and a valve disposed in the supply or discharge line to adjust a flow rate of the refrigerant.

In still other embodiments, the inlet port may be disposed above the outlet port, and the substrate processing apparatus may further include a refrigerant supply device connected to the supply line and the discharge line to cool the refrigerant discharged through the discharge line, thereby supply the cooled refrigerant into the supply line.

In even other embodiments, the process chamber may include: an inlet port disposed on one side of the process chamber to allow the tube type heater to be taken in; and an outlet port disposed on the other side of the process chamber to allow the tube type heater to be taken out, wherein the substrate processing apparatus may further include: a supply line connected to the tube type heater disposed on the inlet port to supply the refrigerant; and an internal reaction tube disposed in the internal space to partition the inner space into the inside and outside, the internal reaction tube having a process space in which the process with respect to the substrate is performed, wherein the tube type heater may have a plurality of injection holes for injecting the refrigerant toward the outside of the internal reaction tube.

In yet other embodiments, the substrate processing apparatus may further include an exhaust port communicating with an exhaust hole defined in an upper portion of the process chamber to exhaust the refrigerant injected through the injection holes to the outside.

In further embodiments, each of the injection holes may be disposed inclined upward.

In still further embodiments, the substrate processing apparatus may further include: a discharge line connected to the tube type heater disposed on the outlet port to discharge the refrigerant within the tube type heater; and a pump disposed on the discharge line to forcibly discharge the refrigerant.

### Advantageous Effects

According to the embodiments of the present invention, the temperature of the process chamber, which increases to the preset temperature, may be easily cooled.

### DESCRIPTION OF DRAWINGS

FIG. 1 is a schematic view of a substrate processing apparatus according to an embodiment of the present invention;

FIG. 2 is a view of a state in which a substrate holder is switched into a process position in FIG. 1;

FIG. 3 is a view of a substrate processing apparatus according to another embodiment of the present invention;

FIG. 4 is a view of a substrate processing apparatus according to another embodiment of the present invention;

FIG. 5 is a view illustrating an arrangement of an injection hole of FIGS. 3 and 4; and

FIG. 6 is an enlarged view of a tube type heater of FIG. 5A.

### BEST MODE

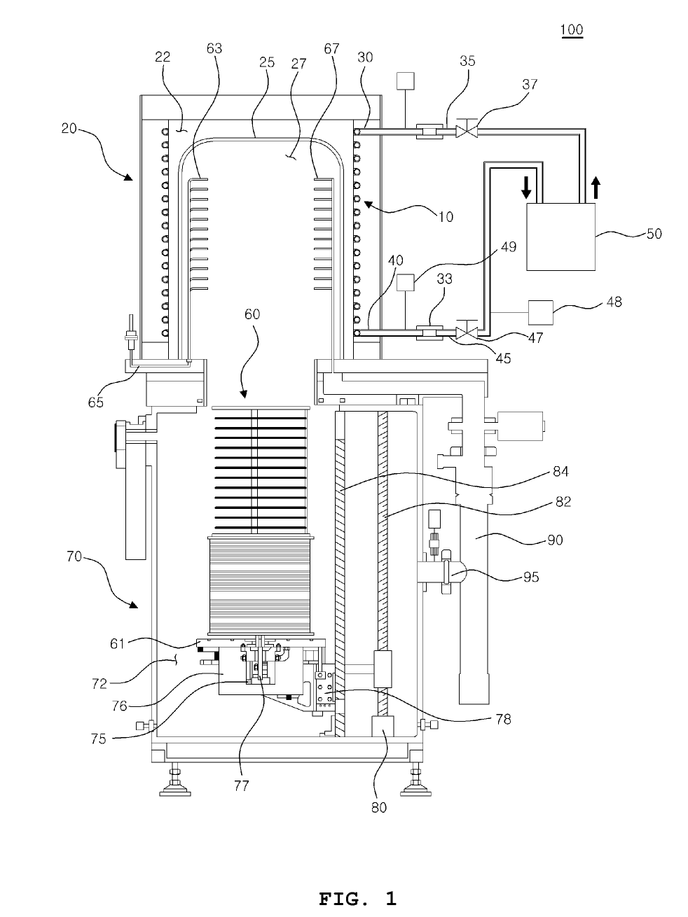

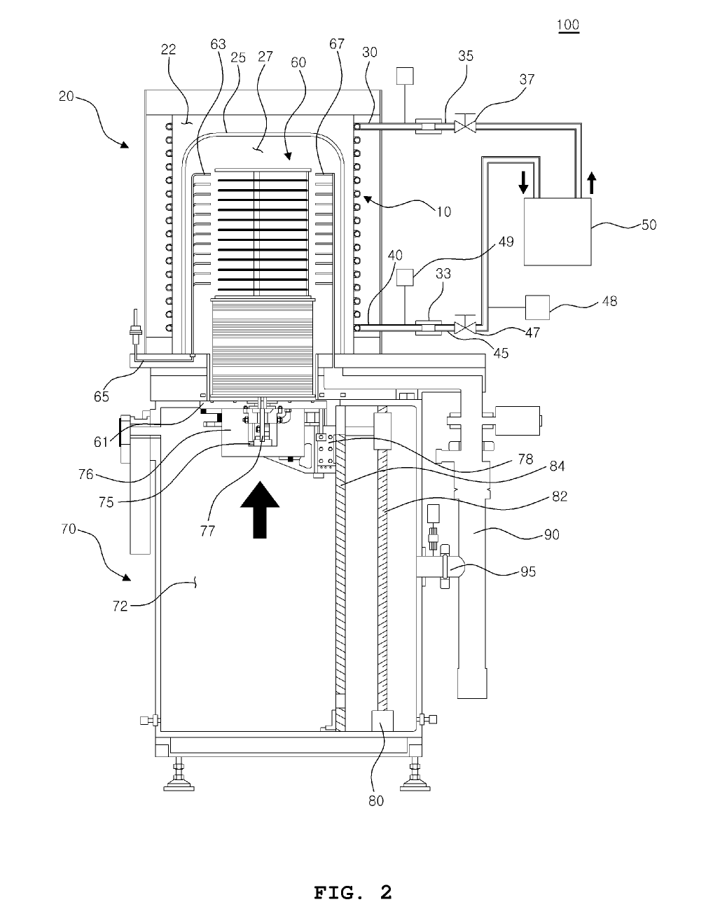

Hereinafter, exemplary embodiments of the present invention will be described in detail with reference to FIGS. 1 to 2. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the thicknesses of layers and regions are exaggerated for clarity. It is obvious to a person skilled in the art that the embodiments of the present invention are applicable to various objects to be processed in addition to the substrate W that is described in the current embodiments.

Typically, a substrate processing apparatus may be classified into a single wafer type substrate processing apparatus in which a substrate processing process is performed on one substrate and a batch type substrate processing apparatus in which a substrate processing process is performed on a plurality of substrates. The single wafer type substrate processing apparatus has an advantage in that its structure is simple. However, the single wafer type substrate process apparatus may be deteriorated in productivity. Thus, the batch type substrate processing apparatus may be in the spotlight.

Also, to perform the crystallization process, the substrate processing apparatus includes a heater for heating a substrate on which a predetermined thin film is formed. For example, a process temperature for crystallizing amorphous silicon, i.e., an internal temperature of a chamber may be about 550° C. to about 600° C. Here, the process temperatures required for processes may be different from each other. Also, a semiconductor device may be manufactured by repeatedly performing deposition, photographing (pattern formation), etching, and cleaning processes on a substrate, e.g., a silicon wafer.

To perform the above-described processes, the inside of a chamber of the substrate processing apparatus may heated to a high temperature, and then, be naturally cooled by turning the heater installed within the chamber off, thereby preparing the next process. That is, it takes a long time to cool the inside of the chamber up to a temperature for required for the next process. As a result, in the performing of the processes with the substrate, an available rate may be reduced to deteriorate productivity. Thus, a substrate processing apparatus in which an internal temperature of a process chamber is capable of being easily cooled will be described below.

FIG. 1 is a schematic view of a substrate processing apparatus according to an embodiment of the present invention, and FIG. 2 is a view of a state in which a substrate holder is switched into a process position in FIG. 1. Referring to FIGS. 1 and 2, a substrate processing apparatus 100 may include a lower chamber 70 having an opened upper portion. The lower chamber 70 has a passage (not shown) through which a substrate passes. The substrate may be loaded into the lower chamber 70 through the passage. A gate valve (not shown) may be disposed outside the passage, and the passage may be opened or closed by the gate valve.

The substrate processing apparatus 100 includes a substrate holder (also, referred to as a “boat”) 60 on which a plurality of substrate are stacked. The substrates loaded from a transfer chamber are vertically stacked on the substrate holder 60. That is, while the substrate holder 60 is disposed in a stacking space (at a stacking position) provided within the lower chamber 70, the substrate may be stacked within the substrate holder 60. The substrate holder 60 is connected to a rotation shaft 77, and the rotation shaft passes through the lower chamber 70 and is connected to an elevation motor 80 and a rotation motor 75. The rotation motor 75 may be disposed on a motor housing 76. The rotation motor 75 may operate, while the process with respect to the substrate is performed, to rotate the substrate holder 60 together with the rotation shaft 77.

The motor housing 76 is fixed to a bracket 78, and the bracket 78 is connected to a lower guide 84 that is connected to a lower portion of the lower chamber 70 and thus is elevated along an elevation rod 82. The bracket 78 is screw-coupled to the elevation rod 82, and the elevation rod 82 is rotated by the elevation motor 80. That is, the elevation rod 82 may be rotated by the rotation of the elevation motor 80. Thus, the bracket 78 and the motor housing 76 may be elevated together with each other.

Thus, the rotation shaft 77 and the substrate holder 60 may be elevated together with each other, and the substrate holder 60 may be switched into the stacking position and a process position by the elevation motor 80. A bellows (not shown) may be disposed between the lower chamber 70 and the motor housing 76 to maintain sealing of the inside of the lower chamber 70.

A process chamber 20 has an inner space 22 in which the process with respect to the substrate is performed. An internal reaction tube 25 is disposed in the inner space 22. The internal reaction tube 25 provides a process space 27 to perform the process with respect to the substrate. The internal reaction tube 25 partitions the inside of the process chamber 20 into the inner space 22 and the process space 27. Thus, when the substrate holder 60 in which the plurality of substrates are accommodated may ascend into the process space 27 and be switched at the process position, a space between the substrate and a process gas may be minimized to perform the process.

Also, a base 61 may be may be disposed under the substrate holder 60 and elevated together with the substrate holder 60 as the rotation shaft 77 is elevated. The base 61 may close an opened lower portion of the internal reaction tube 25 to prevent heat within the internal reaction tube 25 from being transferred into a stacking space 72 within the lower chamber 20.

That is, when the substrate holder 60 ascends, and the substrates are stacked on a slot of the substrate holder 60, the substrate holder 60 may ascend by a preset distance so that the substrates are successively stacked on the next slot of the substrate holder 60. When the substrates are stacked on the substrate holder 60, the substrate holder 60 may ascend into the process chamber 20 and be disposed in the process space 27 to perform the process with respect to the substrate.

That is to say, the process chamber 20 has the inner space 22, in which the substrate transferred from the lower chamber 70 is accommodated, to perform the process with respect to the substrate within the internal reaction tube 25 that partitions the inside of the process chamber into the inner space 22 and the process space 27. A tube type heater 10 is disposed around the inner space 22 in a sidewall of the process chamber 20. An inlet port 30 and an outlet port 40 are disposed on one side and the other side of the process chamber 20, respectively. The tube type heater 10 may be taken in or out through the inlet port 30 and the outlet port 40.

A supply line 35 may be connected to the tube type heater 10 disposed on the inlet port 30 to supply a refrigerant into a passage 5 of the tube type heater 10 therethrough. A discharge line 45 may be connected to the tube type heater 10 disposed on the outlet port 40. Here, the inlet port 30 may be above the outlet port 40. If the refrigerant is coolant, the coolant may be supplied into the inlet port 30 disposed on the upper portion of the process chamber 20 and discharged through the outlet port 40 disposed on the lower portion of the process chamber 20. Thus, the coolant may smoothly flow by using its weight.

Also, the supply line 35 may be connected to the passage 5 of the tube type heater 10 disposed on the inlet port 30 to supply the refrigerant into the passage 5. Also, the discharge line 45 may be connected to the tube type heater 10 disposed on the outlet port 40 to discharge the refrigerant that is heated while passing through the inside of the process chamber 20.

In addition, the supply line 35 and the discharge line 45 may be connected to a chiller 50. The refrigerant heated while passing through the inside of the process chamber 20 may flow into the chiller 50 through the discharge line 45. Here, when the refrigerant is coolant, the coolant supplied by the chiller 50 may be circulated through the supply line 35. On the other hand, when the refrigerant is a cooling gas, the refrigerant heated in a state where the chiller 50 is removed may be discharged to air through the discharge line 45.

Each of the supply line 35 and the discharge line 45 may be connected to the tube type heater 10 through an insulation connection part 33, and a power source 49 for supplying current to the tube type heater 10 may be connected between the insulation connection part 33 and the process chamber 20. The insulation connection part 33 may prevent electricity or heat from flowing into the tube type heater 10 and the supply and discharge lines 35 and 45. The insulation connection part 33 may be formed of an insulation material such as rubber or glass. Also, supply and discharge valves 37 and 47 that are opened or closed to allow the coolant to flow or adjust a flow rate of the coolant may be provided in the supply and discharge lines 35 and 45, respectively. Also, a pump 48 for forcibly discharging the refrigerant flowing along the passage 5 of the tube type heater 10 to the outside may be provided on the discharge line 45.

Thus, when the refrigerant flows along the passage 5 of the tube type heater 10 to reduce a temperature within the process chamber 20 that is heated to a preset temperature, the current applied to the tube type heater 10 may be blocked, and also, the coolant may be supplied into the passage 5 provided in the tube type heater 10 to quickly reduce residual heat of the tube type heater 10.

The substrate processing apparatus 100 may perform the processes at different temperatures when each of the processes is performed. Thus, when the heater is heated at the preset temperature to increase a temperature within the process chamber 20, and then, decrease the temperature within the process chamber to perform the next process, the current applied to the tube type heater 10 may be blocked, and the coolant may be supplied into the passage 5 provided in the tube type heater 10 to cool a heating wire provided in the tube type heater 10, thereby quickly reducing the temperature within the process chamber 20.

Also, the substrate processing apparatus 100 may further include a gas supply unit. The gas supply unit may include a plurality of supply nozzles 63 and exhaust nozzles 67. Supply holes (not shown) of the supply nozzles 63 may be defined at heights different from each other. The supply nozzles 63 and the supply holes may be disposed in the process space 27. The supply nozzles 63 may be connected to an input line 65 provided in the process chamber 20 to supply a reaction gas onto the substrates accommodated in the substrate holder 60.

The exhaust nozzles 67 may be correspondingly disposed at sides opposite to the supply nozzles 63. Like the supply nozzles 63, the exhaust nozzles 67 may be disposed in the process space 27 of the internal reaction tube 25. Also, an exhaust holes (not shown) of the exhaust nozzles 67 may be defined in parallel with the supply holes of the supply nozzles 63. The exhaust nozzles 67 and exhaust holes may have the same number as the supply nozzles 63 and supply holes. The reaction gas supplied through the supply nozzles 63 may flow toward the exhaust nozzles 67. Also, non-reaction gas and byproducts which are generated during the processes may be suctioned through the exhaust nozzles 67 and then exhausted to the outside.

The exhaust nozzles 67 are connected to a first output line 90. The non-reaction gas and byproducts which are suctioned through the exhaust nozzles 67 are discharged through a first output line 90. An output valve (not shown) may be disposed in the first output line 90 to open or close the first output line 90. Also, a turbo pump (not shown) may be disposed on the first output line 90 to forcibly discharge the non-reaction gas and byproducts.

The lower chamber 70 may also include a second output line 95, and the stacking space 72 may be exhausted. Also, the second output line 95 may communicate with the first output line 90. For convenience of description, omitted components and operation processes may be substitute with the explanation of the substrate processing apparatus described with reference to FIGS. 1 and 2, and thus, differences therebetween will be mainly described below.

Although the present invention is described in detail with reference to the exemplary embodiments, the invention may be embodied in many different forms. Thus, technical idea and scope of claims set forth below are not limited to the preferred embodiments.

### MODE FOR INVENTION

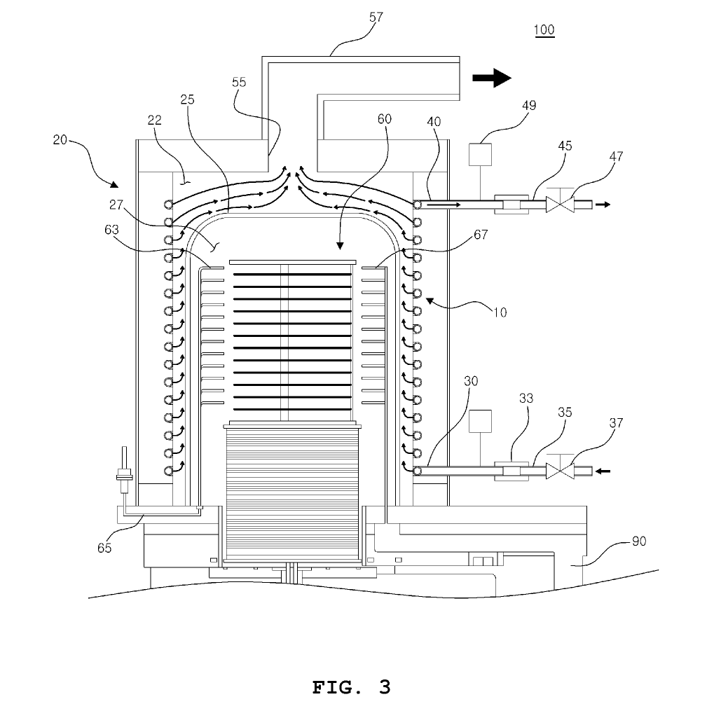

Hereinafter, exemplary embodiments of the present invention will be described in detail with reference to FIGS. 3 to 6. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the thicknesses of layers and regions are exaggerated for clarity. It is obvious to a person skilled in the art that the embodiments of the present invention are applicable to various objects to be processed in addition to the substrate W that is described in the current embodiments.

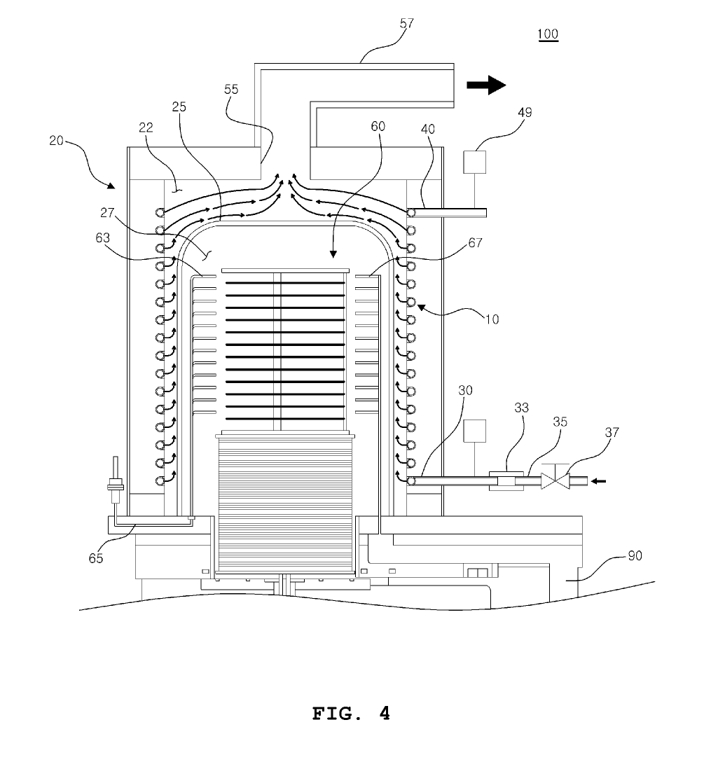

FIG. 3 is a view of a substrate processing apparatus according to another embodiment of the present invention, and FIG. 4 is a view of a substrate processing apparatus according to another embodiment of the present invention. As described above, a process chamber 20 has an inner space 22, in which a substrate transferred from a lower chamber 70 is accommodated, to perform a process with respect to the substrate. A tube type heater 10 is disposed 20 around the inner space 22 in a sidewall of the process chamber.

An inlet port 30 and an outlet port 40 are disposed on one side and the other side of the process chamber 20, respectively. The tube type heater 10 may be taken in or out through the inlet port 30 and the outlet port 40. The inlet port 30 may be disposed under the outlet port 40. Thus, a refrigerant may flow upward. When the refrigerant is a cooling gas, the inlet port 30 may be disposed under the outlet port to supply the cooling gas therethrough. Then, the heated cooling gas may be discharged through the outlet port 40 disposed above the inlet port 30. Thus, the cooling gas may be smoothly discharged by using a specific gravity difference due to the heating of the cooling gas.

A supply line 35 may be connected to the tube type heater 10 disposed on the inlet port 30, and a supply line 35 may be connected to a refrigerant storage tank (not shown) to supply the refrigerant into a passage 5 of the tube type heater 10. That is, the supply line 35 may be connected to the passage 5 of the tube type heater 10 disposed on the inlet port 30 to supply the refrigerant into the passage 5. Also, a discharge line 45 may be connected to the tube type heater 10 disposed on the outlet port 40 to discharge the refrigerant that is heated while passing through the inside of the process chamber 20. Also, a pump (not shown) for easily discharging the refrigerant may be connected to the discharge line 45 of the tube type heater 10 disposed on the outlet port 40.

As shown in FIG. 3, the tube type heater 10 has injection holes 7 for injecting the refrigerant into an inner space 22 of the process chamber 20. The injection holes 7 may inject the refrigerant toward the outside of an internal reaction tube 25. Here, the refrigerant may be a refrigerant gas including nitrogen. An exhaust hole 20 may be defined in an upper portion of the process chamber 20. An exhaust port 57 may communicate with the exhaust hole 55 to discharge the refrigerant injected through the injection holes 7 to the outside.

That is, the substrate processing apparatus 100 may quickly cool a temperature of the tube type heater 10 that increases in temperature. The refrigerant may be injected toward the outside of the internal reaction tube 25 through the plurality of injection holes 7 defined in the tube type heater 10 to effectively reduce a temperature of the internal reaction tube 25 that increases in temperature, thereby quickly controlling a process temperature required fro the next process.

As shown in FIG. 4, the substrate processing apparatus 100 may block the discharge line 45 of the tube type heater 10 disposed on the outlet port 40 to inject the entire refrigerant supplied through the supply line 35 toward the internal reaction tube 25. In the substrate processing apparatus 100 as described above, when a temperature of the heater is reduced to a preset temperature by the refrigerant flowing close to the tube type heater 10, the entire refrigerant may be injected into the internal reaction tube 25 to quickly reduce a temperature of a process space in which the process is performed.

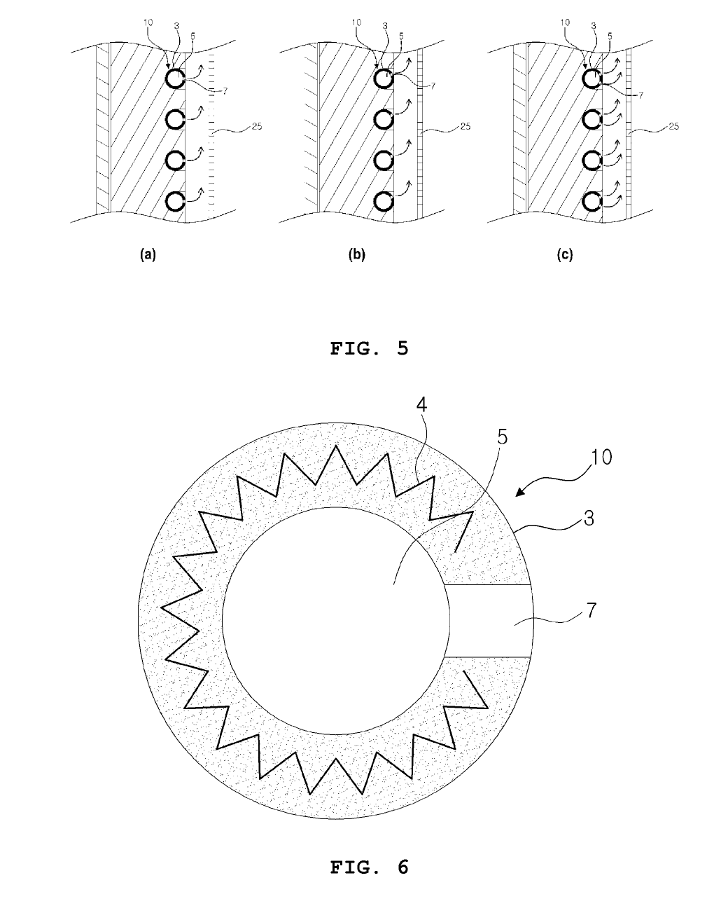

FIGS. 5A to 5C are views illustrating positions of the injection holes according to embodiments of the present invention, and FIG. 6 is an enlarged view of a tube type heater of FIG. 5A. Referring to FIGS. 5 and 6, a tube type heater 10 may have a circular or polygonal section. A passage 5 may be defined in an inner surface of the tube type heater 10. For example, the tube type heater 10 may be spirally disposed in a through type in a sidewall of a process chamber. The tube type heater 10 may include a heater body 3 having a thickness corresponding to a preset outer circumferential surface and the passage 5 defined along an inner circumferential surface of the heater body 3. A heating wire 4 may be provided in the heater body 3, and the power supply 49 supplies current to the heating wire 4. The tube type heater 10 has a plurality of injection holes for injecting a refrigerant toward the outside of an internal reaction tube 25.

As shown in FIGS. 5A and 5B, each of the injection holes 7 may be defined in a central portion of a circumferential surface of the tube type heater 10 and be disposed inclined upward toward the outside of the internal reaction tube 25. Also, air current may be formed in the injection holes 7 to allow a cooling gas to smoothly flow toward an exhaust hole 55. Also, as shown in FIG. 5C, the injection holes 7 may be vertically provided in plurality. Since the refrigerant is uniformly injected toward the internal reaction tube 25 through the injection holes 7 defined at preset positions, the tube type heater 10 and an internal temperature of a process chamber 20 may be effectively cooled.

That is, to solve the above-described limitations, the inside of the process chamber may increase to a high temperature to perform one process, and then, the refrigerant may be supplied into the tube type heater 10 to cool the inside of the process chamber so as to perform the other process. Therefore, the tube type heater 10 increasing in temperature and the inside of the process chamber 20 may be easily cooled. Thus, the process time may be effectively reduced to increase process efficiency with respect to the substrate, thereby improving productivity.

According to the embodiments of the present invention, the temperature of the process chamber, which increases to the preset temperature, may be easily cooled.

Although the present invention is described in detail with reference to the exemplary embodiments, the invention may be embodied in many different forms. Thus, technical idea and scope of claims set forth below are not limited to the preferred embodiments.

### INDUSTRIAL APPLICABILITY

The present invention may be applicable to a various apparatus for manufacturing semiconductor or a various method for manufacturing semiconductor.

1. A substrate processing apparatus comprising:
a process chamber having an inner space in which a substrate is accommodated, and a process with respect to the substrate is performed; and
a tube type heater disposed around the inner space in a sidewall of the process chamber, the tube type heater having a passage through which a refrigerant supplied from the outside flows.

2. The substrate processing apparatus of claim 1, wherein the process chamber comprises:
an inlet port disposed on one side of the process chamber to allow the tube type heater to be taken in; and
an outlet port disposed on the other side of the process chamber to allow the tube type heater to be taken out,
wherein the substrate processing apparatus further comprises:
a supply line connected to the tube type heater disposed on the inlet port to supply the refrigerant; and
a discharge line connected to the tube type heater disposed on the outlet port to discharge the refrigerant within the tube type heater.

3. The substrate processing apparatus of claim 2, further comprising:
an insulation connection part connecting the tube type heater to each of the supply and discharge lines;
a power source disposed between the process chamber and the insulation connection part to supply current to the tube type heater; and
a valve disposed in the supply or discharge line to adjust a flow rate of the refrigerant.

4. The substrate processing apparatus of claim 2, wherein the inlet port is disposed above the outlet port, and
the substrate processing apparatus further comprises a refrigerant supply device connected to the supply line and the discharge line to cool the refrigerant discharged through the discharge line, thereby supply the cooled refrigerant into the supply line.

5. The substrate processing apparatus of claim 1, wherein the process chamber comprises:
an inlet port disposed on one side of the process chamber to allow the tube type heater to be taken in; and
an outlet port disposed on the other side of the process chamber to allow the tube type heater to be taken out,
wherein the substrate processing apparatus further comprises:
a supply line connected to the tube type heater disposed on the inlet port to supply the refrigerant; and
an internal reaction tube disposed in the internal space to partition the inner space into the inside and outside, the internal reaction tube having a process space in which the process with respect to the substrate is performed,
wherein the tube type heater has a plurality of injection holes for injecting the refrigerant toward the outside of the internal reaction tube.

6. The substrate processing apparatus of claim 5, further comprising an exhaust port communicating with an exhaust hole defined in an upper portion of the process chamber to exhaust the refrigerant injected through the injection holes to the outside.

7. The substrate processing apparatus of claim 5, wherein each of the injection holes is disposed inclined upward.

8. The substrate processing apparatus of claim 5, further comprising:
a discharge line connected to the tube type heater disposed on the outlet port to discharge the refrigerant within the tube type heater; and
a pump disposed on the discharge line to forcibly discharge the refrigerant.

9. The substrate processing apparatus of claim 3, wherein the inlet port is disposed above the outlet port, and
the substrate processing apparatus further comprises a refrigerant supply device connected to the supply line and the discharge line to cool the refrigerant discharged through the
discharge line, thereby supply the cooled refrigerant into the supply line.

10. The substrate processing apparatus of claim 6, wherein each of the injection holes is disposed inclined upward.

11. The substrate processing apparatus of claim 6, further comprising:
a discharge line connected to the tube type heater disposed on the outlet port to discharge the refrigerant within the tube type heater; and
a pump disposed on the discharge line to forcibly discharge the refrigerant.
